(19) United States
(12) Patent Application Publication
(10) Pub. No.: US 2025/0022137 A1
(43) Pub. Date: Jan. 16, 2025

(54) Method and System for Brain Tissue Segmentation from CT Scans

(71) Applicants: Nanyang Technological University, Singapore (SG); Singapore Health Services Pte Ltd., Singapore (SG)

(72) Inventors: Jagath Chandana RAJAPAKSE, Singapore (SG); Mukun GUO, Singapore (SG); Wei Kwek SOH, Singapore (SG); Yi Hao CHAN, Singapore (SG); Ling Ling CHAN, Singapore (SG)

(73) Assignees: Nanyang Technological University, Singapore (SG); Singapore Health Services Pte Ltd., Singapore (SG)

(21) Appl. No.: 18/712,094

(22) PCT Filed: Nov. 18, 2022
(86) PCT No.: PCT/SG2022/050837

§ 371 Date: May 21, 2024

(30) Foreign Application Priority Data
Nov. 22, 2021 (SG) 10202112974P

(51) Int. Cl. G06T 7/11; G06T 7/00; G06T 7/174

(52) U.S. Cl. CPC G06T 7/11; G06T 7/0012; G06T 7/174; G06T 2207/10081; G06T 2207/10088; G06T 2207/20081; G06T 2207/30016

(57) ABSTRACT

Disclosed herein is a method for training a system to segment a computerized tomography (CT) image, comprising receiving a plurality of data groups, each group comprising an image pair comprising a CT image, a magnetic resonance (MR) image and a segmentation mask for the MR image; training a first generator of a first generative adversarial network (GAN) using the image pairs, to generate a synthetic MR image from a CT image based on relationships between image features of the CT image and MR image in each image pair; and training a second generator of a second GAN to generate a synthetic mask for the synthetic MR image based on relationships between features of the synthetic MR image and segmentation mask of each data group.

### TECHNICAL FIELD

The present invention relates, in general terms, to methods and systems for brain tissue segmentation, and more specifically relates to methods and systems for brain tissue segmentation from CT scans.

### BACKGROUND

Computerized tomography (CT) and magnetic resonance (MR) scans of brains are routinely used in neurology clinics for diagnosis and treatment planning. They are both capable of mapping brain structures in a non-invasive manner.

In these processes, delineation of different tissues in the image can be very helpful to doctors and has several clinical applications. Compared to MR scans, CT images are usually cheaper and faster to obtain.

However, MR scans have higher soft tissue contrast. Consequently, well-established methods have been proposed to automatically segment tissues in MR brain scans, but few works have been done in the CT domain.

It would be desirable to overcome or ameliorate at least one of the above-described problems, or at least to provide a useful alternative.

### SUMMARY

Disclosed herein is method for training a system to segment a computerized tomography (CT) image, comprising:
receiving a plurality of data groups, each group comprising an image pair comprising the CT image, a magnetic resonance (MR) image and a segmentation mask for the MR image;
training a first generator of a first generative adversarial network (GAN) using the image pairs, to generate a synthetic MR image from the CT image based on relationships between image features of the CT image and MR image in each image pair; and
training a second generator of a second GAN to generate a synthetic mask for the synthetic MR image based on relationships between features of the synthetic MR image and segmentation mask of each data group.

Advantageously, in some embodiments, the first generator and second generator are trained together.

Advantageously, in some embodiments, the first GAN comprises a first discriminator and the second GAN comprises a second discriminator, the first discriminator being trained before training the second discriminator.

Advantageously, in some embodiments, training the first GAN comprises enforcing pixel-level loss between the MR image and respective synthetic MR image.

Advantageously, in some embodiments, training the second GAN comprises enforcing Binary Cross Entropy Loss between the synthetic MR image and respective synthetic mask.

Advantageously, in some embodiments, the objective function of the first GAN, [symbol] _{GAN-1}, is formulated as a first conditional GAN, [symbol] _{cGAN-1}, according to:

$${ℒ}_{GAN - 1} = {ℒ}_{cGAN - 1} ( {G}_{1} ( x , z ) , {D}_{1} ( x , y ) ) + {λℒ}_{1} ( y , {G}_{1} ( x , z ) )$$

swhere G₁ is the first generator, D₁ is a first discriminator of the first GAN, x and y are the CT image and MR image of each pair, respectively, z is a random noise vector, [symbol] ₁ is a loss based on the L₁ distance and α is a regularisation parameter.

Advantageously, in some embodiments, the objective function of the second GAN, [symbol] _{GAN-2}, is formulated as a first conditional GAN, [symbol] _{cGAN-2}, according to:

$${ℒ}_{GAN - 2} = {ℒ}_{cGAN} ( {G}_{2} ( {G}_{1} ( x , z ) , {z}^{′} ) , {D}_{2} ( {G}_{1} ( x , z ) , {y}^{′} ) ) + {λℒ}_{B} ( {y}^{′} , {G}_{2} ( {G}_{1} ( x , z ) , {z}^{′} ) )$$

where G₁ and G₂ are the first generator and second generator, respectively, D₁ and D₂ are a first discriminator of the first GAN and second discriminator of the second GAN, respectively, x and y are the CT image and MR image of each pair, respectively, y′ is the synthetic MR image, z and z′ are random noise vectors, [symbol] _{B} is a loss based on the Binary Cross Entropy Loss and γ is a regularisation parameter.

Advantageously, in some embodiments, the method further comprises segmenting a further CT image, by:
receiving the further CT image;
converting the further CT image to a synthetic magnetic resonance (MR) image using the first generator;
generating a segmentation mask for the synthetic MR image using the second generator; and
applying the segmentation mask to the CT image.

Disclosed herein is a method for generating synthetic computerized tomography (CT) images, comprising:
for each of a plurality of subjects, receiving a magnetic resonance (MR) image for the subject;
training a first generator to generate a synthetic CT image based on the MR image; and
training a second generator to generate a reconstructed MR image based on the synthetic CT image and/or an original CT image.

Advantageously, in some embodiments, the method further comprises, after training the first generator, generating a synthetic CT image by: receiving a further MR image;
applying the first generator to the further MR image to generate a synthetic CT image corresponding to the further MR image (corresponding synthetic CT image); and
creating an image pair comprising the corresponding synthetic CT image and the further MR image.

Disclosed herein is a system for segmenting a computerized tomography (CT) image, comprising:
memory;
at least one processor; and
a machine learning module comprising one or more trained, machine learning models,
the memory storing instructions that, when executed by the at least one processor, cause the at least one processor to:
   receive a plurality of data groups, each group comprising an image pair comprising the CT image, a magnetic resonance (MR) image and a segmentation mask for the MR image;
   train a first generator of a first generative adversarial network (GAN) of the machine learning module using the image pairs, to generate a synthetic MR image from the CT image based on relationships between image features of the CT image and MR image in each image pair; and
   train a second generator of a second GAN of the machine learning module to generate a synthetic mask for the synthetic MR image based on relationships between features of the MR image and segmentation mask of each data group.

Advantageously, in some embodiments, the instructions further cause the at least one processor to segment a further CT image by:
receiving the further CT image;
converting the CT image to a synthetic MR image using the first generator;
generating a segmentation mask for the synthetic MR image using the second generator; and
applying the segmentation mask to the CT image.

Disclosed herein is a system for generating a synthetic computerized tomography (CT) image, comprising:
memory;
at least one processor; and
a machine learning module comprising one or more trained, machine learning models,
the memory storing instructions that, when executed by the at least one processor, cause the at least one processor to:
   for each of a plurality of subjects, receive a magnetic resonance (MR) image for the subject;
   train a first generator of the machine learning module to generate synthetic CT images based on the MR image; and
   training a second generator to generate a reconstructed MR image based on the synthetic CT image and/or an original CT image.

Advantageously, in some embodiments, the instructions, when executed by the at least one processor, further cause the at least one processor to generate a synthetic CT image, after training the first generator, by:
receiving a further MR image; and
applying the first generator to the further MR image to generate a synthetic CT image corresponding to the further MR image; and
creating an image pair comprising the corresponding synthetic CT image and the further MR image.

Disclosed herein is a method for segmenting a computerized tomography (CT) image, comprising:
receiving a CT image;
converting the CT image to a synthetic magnetic resonance (MR) image;
generating a segmentation mask for the synthetic MR image; and
applying the segmentation mask to the CT image.

Disclosed herein is a system for segmenting a computerized tomography (CT) image, comprising:
memory;
at least one processor; and
a machine learning module comprising one or more trained, machine learning models,
   the memory storing instructions that, when executed by the at least one processor, cause the at least one processor to:
   receive a CT image;
   convert the CT image to a synthetic magnetic resonance (MR) image using the machine learning module;
   generating a segmentation mask for the synthetic MR image using the machine learning module; and
   apply the segmentation mask to the CT image.

### BRIEF DESCRIPTION OF THE DRAWINGS

Embodiments of the present invention will now be described, by way of non-limiting example, with reference to the drawings in which:

FIG. 1 illustrates an example method for generating synthetic computerized tomography (CT) images;

FIG. 2 illustrates synthetic CT scan generation by using a CycleGAN pipeline;

FIG. 3 illustrates training of the segmentation pipeline;

FIG. 4 illustrates tissue segmentation from CT scan images;

FIG. 5 illustrates segmentation results and intermediate synthetic MR scans;

FIG. 6 illustrates segmentation results and intermediate synthetic MR scans for various segmentation tasks; and

FIG. 7 relates to a block diagram showing an exemplary computer device, in which embodiments of the invention may be practiced.

### DETAILED DESCRIPTION

The present invention addresses the problem of segmentation of brain tissues (i.e., grey matter, white matter, cerebrospinal fluid (CSF)) and ventricles from CT scans. Leveraging on the recent success of generative adversarial networks (GANs), the present disclosure proposes a novel analysis pipeline that recovers intrinsic tissue information in CT images and utilizes such information for segmentation of brain tissues. The pipeline performs segmentation by performing two tasks. First, it generates synthetic MR scans from the input CT brain scans. Second, it generates the tissue segmentation consisting of three tissue types from the synthetic MR scans. The synthetic MR scan generation pipeline was trained end-to-end using unpaired MR and CT images. The tissue mask generation pipeline was trained with paired CT and MR images and pre-annotated tissue masks from MR images. The present disclosure demonstrates that the proposed method outperforms the state-of-the-art segmentation methods on publicly available datasets.

Herein proposed is a tissue segmentation pipeline that segments CT brain scans by training GANs to recover the intrinsic information that is only available in the MR domain. The present methodology therefore enables CT brain tissue segmentation by leveraging information from synthetically generated MR scans. The present pipeline recovers visual information that is only available in the CT domain by utilizing a generator that generates corresponding MR scans. With the synthetic MR scans, more features of tissues can be captured by the pipeline to achieve good segmentation results.

The present disclosure focusses on CT brain scan segmentation with deep learning and GANs while most automated segmentation techniques of brain images still heavily rely on traditional statistical modelling approaches such as atlas-based Bayesian methods. Atlas-based segmentation typically requires age-specific templates and takes about 20 minutes to process one image. The proposed method only requires CT brain scan slices as input and is able to process hundreds of images within minutes. Compared to the atlas-based methods, the proposed pipeline demonstrates significant advantages in usability and efficiency. Several efforts have been made in leveraging GAN to tackle CT-related problems, but they mostly leverage GAN as a data augmentation tool rather than in the generation of synthetic MR images from which to generate a mask to identify tissue in a corresponding CT scan.

In the following, the present disclosure will present both the generation of synthetic CT images and tissue segmentation pipeline. The tissue segmentation pipeline needs CT and MR brain scans of the same subject (paired images) for training. As datasets of such information are generally not publicly available, the present methods include a method for preparing data in the required format. We start with the Internet Brain Segmentation Repository (IBSR) dataset which contains MR scans of 18 subjects and segmentation masks of grey matter, white matter, and CSF. To acquire the CT scans of the same subject, a Cycle Generative Adversarial Network (CycleGAN) performs cross-modality synthesis of CT scans from MR scans in order to prepare the paired dataset.

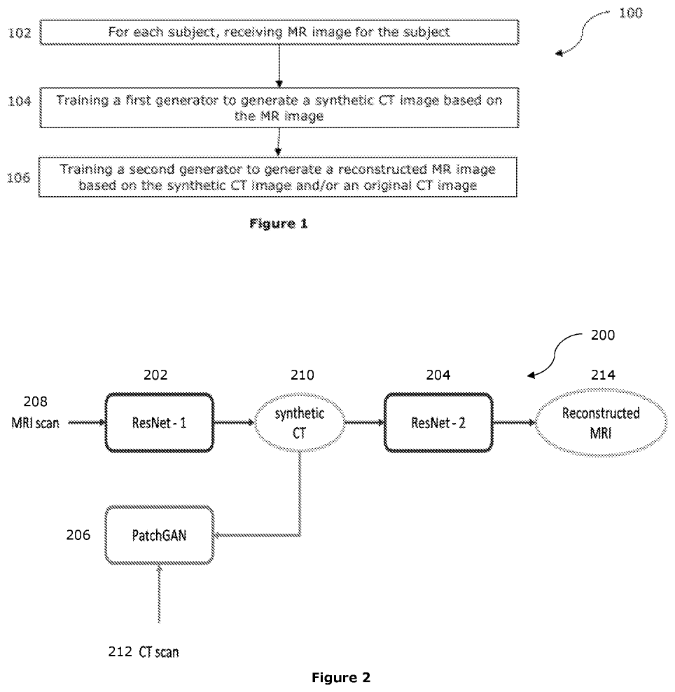

FIG. 1 refers to an example method 100 for generating synthetic computerized tomography (CT) images, comprising:
Step 102: for each of a plurality of subjects, receiving a magnetic resonance (MR) image for the subject;
Step 104: training a first generator to generate a synthetic CT image based on the MR image; and
Step 106: training a second generator to generate a reconstructed MR image based on the synthetic CT image and/or an original CT image.

Step 102 can involve receiving a MR image from any suitable source—e.g. directly from the MRI machine or from a database.

FIG. 2 illustrates the synthetic CT scan generation process 200 using the CycleGAN pipeline, which is an approach to training a deep convolutional neural network for image-to-image translation tasks. The CycleGAN pipeline learns a mapping between input and output images using an unpaired dataset—i.e. the MR images and CT images using by the CycleGAN pipeline may not be matched, and may be from different subjects. As shown in FIG. 2, ResNet-1 202 (i.e., the first generator trained at step 104) and ResNet-2 204 (i.e., the second generator trained at step 104) are the generators and PatchGAN 206 is used as the discriminator.

As illustrated in FIGS. 1 and 2, a CycleGAN is trained using 181 MR scans from the Parkinson's Progression Markets Initiative (PPMI) dataset and 491 CT scans from the CQ500 dataset. First, the skull is stripped from the scans and the scans are registered to the same plane-this can be performed by various methods and is presently achieved using the FLIRT and FNIRT tools from FMRIB Software Library v6.0 (FSL). Additionally, scans with visible defects were excluded. ResNet-1 202 with 9 residual blocks was used as the generator, to generate synthetic CT scans from real MR scans, and PatchGAN 206 as the discriminator. The training was performed by enforcing pixel-level loss, adversarial loss, and cycle-consistency loss simultaneously following the standard setting.

After training, we used the generator ResNet-1 202, which has been trained to translate MR scans into synthetic CT scans, to generate synthetic CT scans. FIG. 2 refers to an example method 200 for generating the synthetic CT image by:
receiving a (further) MR image 208;
applying the first generator (ResNet-1 202) to the further MR image (with the help of PatchGAN 206) to generate a synthetic CT image corresponding to the further MR image (corresponding synthetic CT image 210); and
creating an image pair (not shown in FIG. 2) comprising the corresponding synthetic CT image and the further MR image.

During the generation of the synthetic CT scans 200, the present disclosure fed MR scans from the IBSR dataset into the generator ResNet-1 206 and acquired corresponding synthetic CT scans 210 of the subject. Finally, we merge the synthetic CT scans with the original IBSR dataset and produce a new paired dataset, which we will refer to as the paired IBSR dataset in this disclosure. The paired IBSR dataset contains three parts: synthetic CT scans 210, real MR scans 208, and pre-annotated segmentation mask of tissues—the pre-annotated masks may be masks previously generated by a human physician, or through another method such as machine learning mask generation for MR images. This dataset was split into a training set and a test set, which contain scans of 13 subjects and 5 subjects respectively. Despite this paired dataset potentially not perfectly reflecting the distribution of real CT scans, it still produces meaningful information close to real paired images. It will be appreciated that at step 106 of method 100, a second generator 204 was trained to generate a reconstructed

MR image 214 based on the synthetic CT image 210 and/or an original CT image 212. This second generator, ResNet-2 204, which may have the same architecture as ResNet-1 202 (e.g. 9 residual blocks), may be trained by enforcing pixel level loss between the reconstructed MR images, constructed from the corresponding synthetic CT scans, and the real MR images corresponding to the synthetic CT scans.

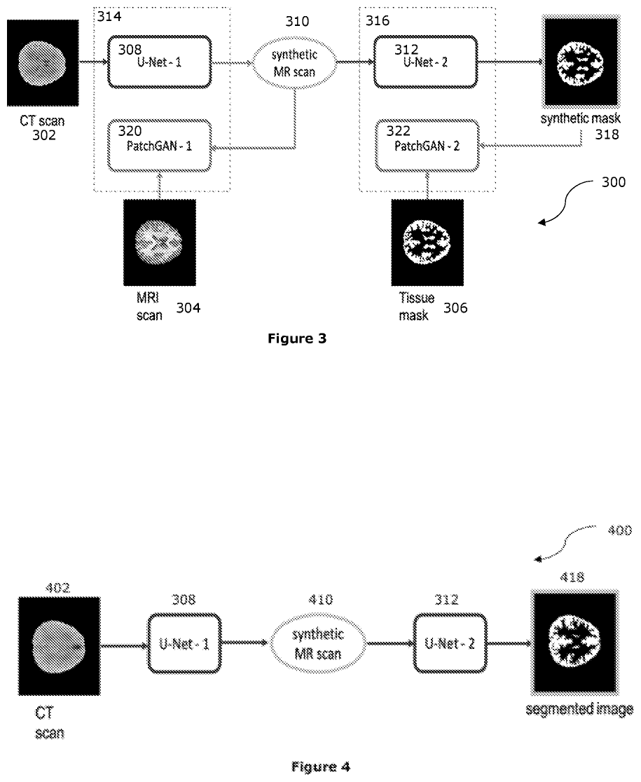

FIG. 3 illustrates the tissue segmentation pipeline, providing an example method 300 for training a system to segment a computerized tomography (CT) image 302. The method 300 involves:
receiving a plurality of data groups, each group comprising an image pair comprising a CT image 302, a magnetic resonance (MR) image 304 and a segmentation mask 306 for the MR image 304;
training a first generator 308 of a first generative adversarial network (GAN) 314 using the image pairs, to generate a synthetic MR image 310 from a CT image based on relationships between image features of the CT image and MR image in each image pair; and
training a second generator 312 of a second GAN 316 to generate a synthetic mask 318 for the synthetic MR image 310 based on relationships between features of the synthetic MR image 310 and segmentation mask 318 of each data group.

In general, the segmentation pipeline consists of two U-Net and two PatchGAN as illustrated in FIG. 3. The two U-Net 308 and 312 are treated as generators. Advantageously, in some embodiments, the first GAN 314 comprises a first discriminator 320 and the second GAN 316 comprises a second discriminator 322. The first discriminator 320 may be trained before training the second discriminator 322. In the present disclosure, the two PatchGAN 320 and 322 are treated as discriminators. The discriminators 320 and 322 are classifiers. They try to distinguish real data from the data created by the generators 308 and 312. It could use any network architecture appropriate to the type of data being classified. The proposed pipeline takes in three inputs during training: the paired CT scan 302, the MR scan 304, and tissue mask 306 of the same subject. The objective of the U-Net-1 308 is to generate intermediate synthetic MR scans from the input CT scans. The intermediate MR scans are then directly fed into the U-Net-2 312 to generate the synthetic segmentation mask 318.

The whole pipeline 300 may be optimized in multiple stages. First, the two U-Net 308 and 312 are optimized, which may occur sequentially. Advantageously, in some embodiments, the first generator 308 and second generator 312 are trained and optimized together. Then, two PatchGAN 320 and 322 are optimized sequentially. Adversarial training is performed between U-Net—PatchGAN pairs.

In some embodiments, training the first GAN comprises enforcing pixel-level loss between the MR image and respective synthetic MR image. In particular, at the second step, pixel-level loss (i.e., L₁ loss) between intermediate synthetic MR scans 310 and input MR scans 304 was enforced.

In some embodiments, training the second GAN comprises enforcing Binary Cross Entropy Loss between the synthetic MR image 310 and respective synthetic mask 318. In particular, at the third step, for the translation between the intermediate synthetic MR scans 310 and the synthetic masks 318, Binary Cross Entropy loss was enforced instead of pixel-level loss. The loss functions will be formally discussed later. It will be appreciated that the architectures enclosed in the squares 314 and 316 can be viewed as a pix2pix model. However, compared to pix2pix, the proposed pipeline implicitly imposed another level of supervision to U-Net-1 308.

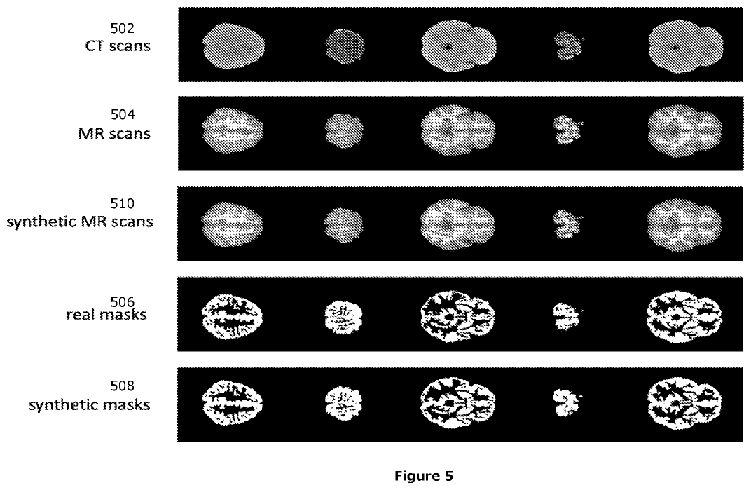

FIG. 4 illustrates an example process 400 for tissue segmentation 418 from CT scan 402. The method 400 comprises segmenting a further CT image, by:
receiving the further CT image 402;
converting the further CT image to a synthetic magnetic resonance (MR) image 410 using the first generator 308;
generating a segmentation mask 418 for the synthetic MR image 410 using the second generator 312; and
applying the segmentation mask 418 to the CT image 402.

In the proposed method 400, the output (that is, the segmentation image 410) of U-Net-2 312 (i.e., segmentation) depends on the output (that is, the created synthetic MR scan 410) of U-Net-1 308 (i.e., intermediate synthetic MR scan). Hence, during the training of the two U-Net, they co-adapted to each other to produce the best synthetic mask. During inference, the two trained U-Net 308 and 312 segmented tissues from CT scans 402. The input CT scan 402 was first fed into the U-Net-1 308, whose output was then fed into the U-Net-2 to get the tissue segmentation 418. Unlike common segmentation models which output the binary label of the input image, the proposed pipeline 400 produces a one-channel image where tissues are represented with pixels of tissue intensities corresponding to tissue classes.

Regarding the loss functions involved in the training phase of the present segmentation pipeline, shown in FIGS. 3 and 4, the objective of the proposed pipeline is composed of two stages. These correspond to synthetic MR scan generation and generation of tissue segmentation, respectively. The two parts can be viewed as two conditional GANs. In this section, G₁, G₂, D₁, and D₂ will represent the two U-Net generators and the two PatchGAN discriminators, respectively. Let x and y denote paired input CT image and MR image, respectively, and the tissue-segmented CT image is given by G₂(G₁(x)).

The objective function of a conditional GAN-1 can be expressed as:

$${ℒ}_{cGAN - 1} ( {G}_{1} ( x , z ) , {D}_{1} ( x , y ) ) = {E}_{xy} [ log ( {D}_{1} ( x , y ) ) ] + {E}_{x , z} [ log ( 1 - {D}_{1} ( x , {G}_{1} ( x , z ) ) ) ]$$

where z is a random noise vector. Investigations showed that adding a more traditional loss would be beneficial to the model's overall performance. Thus, the Li loss was added. This can be expressed as:

$${ℒ}_{1} ( y , {G}_{1} ( x , z ) ) = {E}_{x , y , z} [ {‖ y - {G}_{1} ( x , z ) ‖}_{1} ]$$

The objective function of the first stage is:

$${ℒ}_{GAN - 1} = {ℒ}_{cGAN - 1} ( {G}_{1} ( x , z ) , {D}_{1} ( x , y ) ) + {λ}_{1} {ℒ}_{1} ( y , {G}_{1} ( x , z ) )$$

where λ represents a tunable parameter used to balance between the two losses.

For the second stage, experiments showed that replacing the L₁ distance with the Binary Cross Entropy loss produces slightly better results. Hence, the loss can be expressed as:

$${ℒ}_{GAN - 2} = {ℒ}_{cGAN} ( {G}_{2} ( {G}_{1} ( x , z ) , {z}^{′} ) , {D}_{2} ( {G}_{1} ( x , z ) , {y}^{′} ) ) + {λ}_{2} {ℒ}_{B} ( {y}^{′} , {G}_{2} ( {G}_{1} ( x , z ) , {z}^{′} ) )$$

For the second stage, experiments showed that replacing the L₁ distance with the Binary Cross Entropy loss produces slightly better results. Therefore, the objective function of the second GAN 314, [symbol] _{GAN-2}, is formulated as a first conditional GAN, [symbol] _{cGAN-2}, according to:

$${ℒ}_{GAN - 2} = {ℒ}_{cGAN} ( {G}_{2} ( {G}_{1} ( x , z ) , {z}^{′} ) , {D}_{2} ( {G}_{1} ( x , z ) , {y}^{′} ) ) + {λℒ}_{B} ( {y}^{′} , {G}_{2} ( {G}_{1} ( x , z ) , {z}^{′} ) )$$

where y′ is the synthetic MR image, z and z′ are random noise vectors, [symbol] _{B} is a loss based on the Binary Cross Entropy Loss and λ is a regularisation parameter.

The present disclosure will now discuss the setup and results of our experiments and compare the performance of our pipeline to existing common segmentation models.

To demonstrate the utility of Pipeline 1, the paired ISBR dataset is used to generate segmentation of CT images. The dataset contains pseudo-CT and MR scans pairs of 18 subjects, and their corresponding segmentation masks of gray matter, white matter, and CSF. Performance of the present pipeline is evaluated on a gray matter segmentation task. In this experiment, 13 subjects were used for training and 5 subjects were used for testing. The results were evaluated using two commonly used segmentation metrics, namely the Intersection over Union (IoU) score and the dice coefficient (i.e. F1 score).

In addition, another dataset of paired CT and MRI data was used to evaluate the effectiveness of Pipeline 2. This dataset comes from the CERMEP-IDB-MRXFDG database which is made up of 37 healthy adults with paired CT and MR scans. In experiments, 27 subjects were used for training and 10 subjects were used for testing. IoU and dice coefficient are also used as evaluation metrics, but this set of experiments cover more tasks: tissue segmentation (gray matter, white matter, CSF), brain extraction and ventricle segmentation. Ground truth labels for brain extraction and ventricle segmentation were generated using

FreeSurfer on the T1 MR scans while ground truth labels for tissue segmentation tasks were generated via FSL on the T1 MR scans as well.

The performance of the present pipelines were compared to that of existing techniques as reflected in Table 1. Table 1 shows the comparison of three methods (i.e., U-Net, Pix2pix, and the method proposed in this disclosure) on the grey matter segmentation task. As seen, the present pipeline is superior to the other two in terms of both evaluation metrics. The present pipeline is trained with the Adam optimizer with learning rate of 1e-3. The models were trained for 200 epochs with a batch size of 40. Note that during training, a weight of 10 was assigned on the losses incurred by the first U-Net ( [symbol] _{GAN-1}), while maintaining the weight of the second U-Net ( [symbol] _{GAN-2}) as 1 for the first 20 epochs. Experiments showed that this could improve the model performance slightly.

Thus in some embodiments, the weight for training the first network is greater than that for training the second network, preferably by a factor of 10. This weight differential may be maintained for a predetermined number of epochs.

TABLE 1

| Method | IoU | Dice coefficient |
|---|---|---|
| U-Net | 0.803 | 0.877 |
| Pix2pix | 0.774 | 0.861 |
| The proposed method | 0.808 | 0.882 |

Qualitative comparisons in FIG. 5 show the similarity of the present masks with those of the corresponding ground truth masks. In particular, FIG. 5 illustrates segmentation results and intermediate synthetic MR scans. CT scans (502), MR scans (504), and real masks (506) were inputs to the pipeline. Synthetic MR scans (510) and synthetic masks (508) were produced by the pipeline.

With regard to performance against existing techniques on paired dataset, Table 2 shows the comparison of the three methods on a wider array of tasks performed on the CERMEP-IDB-MRXFDG database. Since U-Net outperformed pix2pix in Table 1, U-Net was used as the baseline comparison. It is evident that the proposed approach can achieve similar performance as U-Net, but also perform better in the ventricle segmentation task.

TABLE 2

| Segmentation task | U-Net | The present methods |
|---|---|---|
| Gray matter | 0.638 | 0.620 |
| White matter | 0.711 | 0.658 |
| CSF | 0.479 | 0.453 |
| Ventricle | 0.523 | 0.582 |
| Brain extraction | 0.930 | 0.917 |

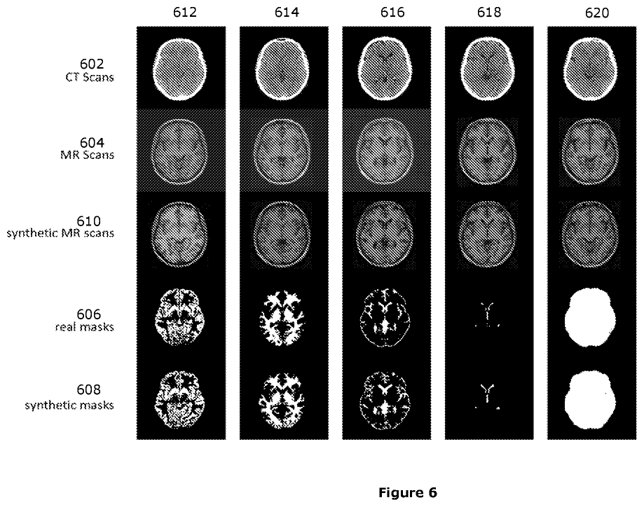

FIG. 6 shows samples of results of the present pipeline for the various tasks. FIG. 6 illustrates segmentation results and intermediate synthetic MR scans for various segmentation tasks: grey matter (column 612), white matter (column 614), CSF (column 616), ventricles (column 618), brain extraction (column 620). Similar to FIG. 5, CT scans (602), MR scans (604), and real masks (606) were inputs to the pipeline. Synthetic MR scans (610) and synthetic masks (608) were produced by the pipeline.

The present invention also relates to a system for performing at least one of the methods performed by the above-proposed pipelines, namely segmenting a CT image, generating a synthetic CT image, and segmenting a CT image. In each case, such a system would include memory and at least one processor and a machine learning module comprising one or more machine learning models. The memory stores instructions that, when executed by the at least one processor, cause the at least one processor to perform the method to achieve the function of the relevant pipeline.

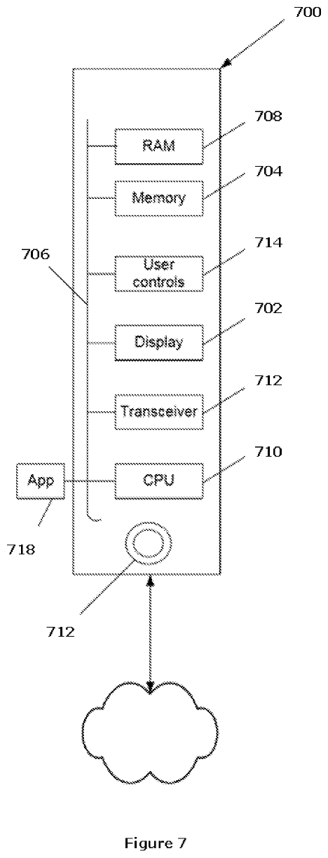

FIG. 7 is a block diagram showing an exemplary embodiment of such a system (such as computer device) 700, in which embodiments of the invention may be practiced. The computer device 700 may be a mobile computer device such as a smart phone, a wearable device, a palm-top computer, and multimedia Internet enabled cellular telephones when used in training the model, and, for use in controlling a vehicle or other machine for autonomous driving, may be an on-board computing system or a mobile device such as an iPhone™ manufactured by Apple™, Inc or one manufactured by LG™, HTC™ and Samsung™, for example, or other device in communication with the vehicle or other machine and configured to send control commands thereto and to receive information on human interventions from the vehicle or other machine.

As shown, the mobile computer device 700 includes the following components in electronic communication via a bus 706:
(a) a display 702;
(b) non-volatile (non-transitory) memory 704;
(c) random access memory (“RAM”) 708;
(d) N processing components 710;
(e) a transceiver component 712 that includes N transceivers; and
(f) user controls 714.

Although the components depicted in FIG. 7 represent physical components, FIG. 7 is not intended to be a hardware diagram. Thus, many of the components depicted in FIG. 7 may be realized by common constructs or distributed among additional physical components. Moreover, it is certainly contemplated that other existing and yet-to-be developed physical components and architectures may be utilized to implement the functional components described with reference to FIG. 7.

The display 702 generally operates to provide a presentation of content to a user, and may be realized by any of a variety of displays (e.g., CRT, LCD, HDMI, micro-projector and OLED displays).

In general, the non-volatile data storage 704 (also referred to as non-volatile memory) functions to store (e.g., persistently store) data and executable code. The system architecture may be implemented in memory 704, or by instructions stored in memory 704.

In some embodiments, the non-volatile memory 704 includes bootloader code, modem software, operating system code, file system code, and code to facilitate the implementation components, well known to those of ordinary skill in the art, which are not depicted nor described for simplicity.

In many implementations, the non-volatile memory 704 is realized by flash memory (e.g., NAND or ONENAND memory), but it is certainly contemplated that other memory types may be utilized as well. Although it may be possible to execute the code from the non-volatile memory 704, the executable code in the non-volatile memory 704 is typically loaded into RAM 708 and executed by one or more of the N processing components 710.

The N processing components 710 in connection with RAM 708 generally operate to execute the instructions stored in non-volatile memory 704. As one of ordinarily skill in the art will appreciate, the N processing components 710 may include a video processor, modem processor, DSP, graphics processing unit (GPU), and other processing components.

The transceiver component 712 includes N transceiver chains, which may be used for communicating with external devices via wireless networks. Each of the N transceiver chains may represent a transceiver associated with a particular communication scheme. For example, each transceiver may correspond to protocols that are specific to local area networks, cellular networks (e.g., a CDMA network, a GPRS network, a UMTS networks), and other types of communication networks.

The system 700 of FIG. 7 may be connected to any appliance 418, such as a MRI machine or CT machine for directly receiving relevant inputs, or a database for extracting MR and/or CT images.

It should be recognized that FIG. 7 is merely exemplary and in one or more exemplary embodiments, the functions described herein may be implemented in hardware, software, firmware, or any combination thereof. If implemented in software, the functions may be stored on or transmitted over as one or more instructions or code encoded on a non-transitory computer-readable medium 704. Non-transitory computer-readable medium 704 includes both computer storage medium and communication medium including any medium that facilitates transfer of a computer program from one place to another. A storage medium may be any available medium that can be accessed by a computer.

The cornerstone of volumetric and morphologic analysis using CT images is segmentation of the brain into different tissue classes. Manual segmentation is marred by poor tissue contrast. It is also cumbersome and time consuming, so automatic segmentation could substantially simplify the procedure. The accurate segmentation of brain tissues in brain images is an important step for detection and treatment planning of brain diseases. Capability of efficiently segmenting tissues brings many exciting business opportunities. While effort has been made to make MR scans cheaper and faster, MR is still many times more expensive and takes much longer time compared to CT scans. Meanwhile, it is not accessible in every hospital. With the possibility of directly recognizing different tissue parts from CT scans, many patients will no longer need to go through the tedious and expensive MR process.

Tissue segmentation including deep grey nuclei of the brain played a crucial role in investigations of learning, behavior, cognition, movement and memory. Automated segmentation strategies can provide insight into the impact of multiple neurological conditions affecting tissues and grey matter structures, such as Multiple Sclerosis (MS), Huntington's disease (HD), Alzheimer's disease (AD), Parkinson's disease (PD) and Cerebral Palsy (CP). Our segmentation approach has overcome several technical challenges limiting an accurate automated segmentation of brain tissues from CT images.

It will be appreciated that many further modifications and permutations of various aspects of the described embodiments are possible. Accordingly, the described aspects are intended to embrace all such alterations, modifications, and variations that fall within the spirit and scope of the appended claims or statements.

Throughout this specification and the claims or statements that follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A method for training a system to segment a computerized tomography (CT) image, comprising:
receiving a plurality of data groups, each group comprising an image pair comprising a CT image, a magnetic resonance (MR) image and a segmentation mask for the MR image;
training a first generator of a first generative adversarial network (GAN) using the image pairs, to generate a synthetic MR image from the CT image based on relationships between image features of the CT image and MR image in each image pair; and
training a second generator of a second GAN to generate a synthetic mask for the synthetic MR image based on relationships between features of the synthetic MR image and segmentation mask of each data group.

2. The method of claim 1, wherein the first generator and second generator are trained together.

3. The method of claim 1, wherein the first GAN comprises a first discriminator and the second GAN comprises a second discriminator, the first discriminator being trained before training the second discriminator.

4. The method of claim 1, wherein training the first GAN comprises enforcing pixel-level loss between the MR image and respective synthetic MR image.

5. The method of claim 1, wherein training the second GAN comprises enforcing Binary Cross Entropy Loss between the synthetic MR image and respective synthetic mask.

6. The method of claim 1, wherein the objective function of the first GAN, [symbol] _{GAN-1}, is formulated as a first conditional GAN, [symbol] c_{GAN-1}, according to:
$$\text{?} ( \text{?} ( \text{?} ) \text{?} ( \text{?} ) ) + \text{?} ( \text{?} ( \text{?} ) )$$
$$\text{?} \text{indicates text missing or illegible when filed}$$
wherein G₁ is the first generator, D₁ is a first discriminator of the first GAN, x and y are the CT image and MR image of each pair, respectively, z is a random noise vector, [symbol] ₁ is a loss based on the L₁ distance and λ is a regularisation parameter.

7. The method of any one of claims 1 te 6 claim 1, wherein the objective function of the second GAN, [symbol] _{GAN-2}, is formulated as a first conditional GAN, [symbol] c_{GAN-2}, according to:
$$\text{?} ( \text{?} ( \text{?} ( \text{?} ) \text{?} ) \text{?} ( \text{?} ( \text{?} ) \text{?} ) ) + \text{?} ( \text{?} ( \text{?} ( \text{?} ) \text{?} ) )$$
$$\text{?} \text{indicates text missing or illegible when filed}$$
wherein G₁ and G₂ are the first generator and second generator, respectively, D₁ and D₂ are a first discriminator of the first GAN and second discriminator of the second GAN, respectively, x and y are the CT image and MR image of each pair, respectively, y′ is the synthetic MR image, z and z′ are random noise vectors, [symbol] _{B} is a loss based on the Binary Cross Entropy Loss and λ is a regularisation parameter.

8. The method of claim 1, further comprising segmenting a further CT image, by:
receiving the further CT image;
converting the further CT image to a synthetic magnetic resonance (MR) image using the first generator;
generating a segmentation mask for the synthetic MR image using the second generator; and
applying the segmentation mask to the CT image.

9. The method of 8 claim 1, wherein the data groups are constructed by:
for each of a plurality of subjects, receiving a magnetic resonance (MR) image for the subject;
training a first generator to generate a synthetic CT image based on the MR image; and
training a second generator to generate a reconstructed MR image based on the synthetic CT image and/or an original CT image.

10. The method of claim 9, further comprising, after training the first generator, generating the synthetic CT image by:
receiving a further MR image;
applying the first generator to the further MR image to generate a synthetic CT image corresponding to the further MR image (corresponding synthetic CT image); and
creating an image pair comprising the corresponding synthetic CT image and the further MR image.

11. A system for segmenting a computerized tomography (CT) image, comprising:
memory;
at least one processor; and
a machine learning module comprising one or more trained, machine learning models,
the memory storing instructions that, when executed by the at least one processor, cause the at least one processor to:
receive a plurality of data groups, each group comprising an image pair comprising the CT image, a magnetic resonance (MR) image and a segmentation mask for the MR image;
train a first generator of a first generative adversarial network (GAN) of the machine learning module using the image pairs, to generate a synthetic MR image from the CT image based on relationships between image features of the CT image and MR image in each image pair; and
train a second generator of a second GAN of the machine learning module to generate a synthetic mask for the synthetic MR image based on relationships between features of the MR image and segmentation mask of each data group.

12. The system of claim 11, wherein the instructions further cause the at least one processor to segment a further CT image by:
receiving the further CT image;
converting the CT image to a synthetic MR image using the first generator;
generating a segmentation mask for the synthetic MR image using the second generator; and
applying the segmentation mask to the CT image.

13. The system of claim 11, wherein the instructions further cause the at least one processor to construct the data groups by:
for each of a plurality of subjects, receiving a magnetic resonance (MR) image for the subject;
training a first generator of the machine learning module to generate synthetic CT images based on the MR image; and
training a second generator to generate a reconstructed MR image based on the synthetic CT image and/or an original CT image.

14. The system of claim 13, wherein the instructions, when executed by the at least one processor, further cause the at least one processor to generate the synthetic CT image, after training the first generator, by:
receiving a further MR image; and
applying the first generator to the further MR image to generate a synthetic CT image corresponding to the further MR image; and
creating an image pair comprising the corresponding synthetic CT image and the further MR image.

15. A method for segmenting a computerized tomography (CT) image, comprising:
receiving a CT image;
converting the CT image to a synthetic magnetic resonance (MR) image;
generating a segmentation mask for the synthetic MR image; and
applying the segmentation mask to the CT image.

16. A system for segmenting a computerized tomography (CT) image, comprising:
memory;
at least one processor; and
a machine learning module comprising one or more trained, machine learning models,
the memory storing instructions that, when executed by the at least one processor, cause the at least one processor to:
receive a CT image;
convert the CT image to a synthetic magnetic resonance (MR) image using the machine learning module;
generating a segmentation mask for the synthetic MR image using the machine learning module; and
apply the segmentation mask to the CT image.
